(19) United States
(12) Patent Application Publication
(10) Pub. No.: US 2026/0143637 A1
(43) Pub. Date: May 21, 2026

(54) FLEXIBLE CUSTOMIZED 3D HEAT PIPE AND ITS PREPARATION METHOD AND APPLICATION

(71) Applicant: XIAMEN UNIVERSITY, Xiamen (CN)

(72) Inventors: Wei ZHOU, Xiamen (CN); Jiarong CUI, Xiamen (CN); Wenjun XU, Xiamen (CN); Weisong LING, Xiamen (CN); Xuyang CHU, Xiamen (CN); Liang SU, Xiamen (CN); Zheng SHEN, Xiamen (CN)

(73) Assignee: XIAMEN UNIVERSITY, Xiamen (CN)

(21) Appl. No.: 19/450,756

(22) Filed: Jan. 16, 2026

Related U.S. Application Data
(63) Continuation of application No. PCT/CN2024/140193, filed on Dec. 18, 2024.

(30) Foreign Application Priority Data
Jul. 19, 2024 (CN) 202410974238.8

(51) Int. Cl. H05K 7/20; B23P 15/26; B29C 64/129; B29C 64/386; B29L 31/00; B33Y 10/00; B33Y 50/00; B33Y 80/00; G06F 30/18

(52) U.S. Cl. CPC H05K 7/20336; B23P 15/26; B29C 64/129; B29C 64/386; B33Y 10/00; B33Y 50/00; B33Y 80/00; G06F 30/18; B23P 2700/09; B29L 2031/757

(57) ABSTRACT

A flexible customized 3D heat pipe, its preparation method, and application are provided. The customized 3D heat pipe partially contacts a control chip to absorb heat generated by the control chip. The remaining part of the customized 3D heat pipe can be laid along any three-dimensional path within an electronic device as needed. The heat accumulated by the control chip is then transferred to any spatial region within the electronic device where the customized 3D heat pipe is laid. This maximizes the heat dissipation area of the heat pipe without affecting the volume of the electronic device or the installation space of other components. Compared to traditional 2D flat heat pipes, it enables more efficient thermal management for electronic devices.

### CROSS REFERENCE TO THE RELATED APPLICATIONS

This application is a continuation application of International Application No. PCT/CN 2024/140193, filed on Dec. 18, 2024, which is based upon and claims priority to Chinese Patent Application No. 202410974238.8, filed on Jul. 19, 2024, the entire contents of which are incorporated herein by reference.

### TECHNICAL FIELD

This application belongs to the technical field of two-phase circulation thermal management devices, specifically relating to a flexible customized three dimensional (3D) heat pipe, its preparation method, and application.

### BACKGROUND

Most emerging electronic devices feature small size, high integration, and irregular shapes, making it difficult to directly apply most thermal management solutions due to limited installation space. Heat pipe technology, with its advantages of small space occupation, high heat transfer efficiency, and low application cost, has become a mainstream cooling solution for addressing high heat flux density issues in small electronic devices.

However, constrained by the requirement for highly sealed heat pipe devices, the complexity and customization of their forms pose significant challenges to sealing processes. This has kept the vast majority of micro heat pipes confined to simple one-dimensional or two-dimensional geometric shapes. Although they have achieved significant application in flat devices like smartphones and laptops, they can only manage heat within the plane of the electronic components in more complexly shaped electronic devices such as AR/VR glasses and cameras, leaving vast unexploited space available for heat distribution.

Additive manufacturing technology is one effective solution to the customization challenge. Most research focuses on utilizing additive manufacturing characteristics to create wick structures with controllable capillary properties, with limited research directly forming complete structures including the housing and wick. The device characteristics of heat pipes require manufacturing processes to meet requirements such as strong sealing, high thermal conductivity, low cost, and lightweight. However, under current technical limitations of Selective Laser Melting (SLM), SLM can only produce thermal management devices whose cost and weight exceed those of the electronic device itself, which is unacceptable.

### SUMMARY

The objective of this application is to provide a flexible customized 3D heat pipe, its preparation method, and application. The customized 3D heat pipe can be laid along any three-dimensional path within an electronic device as needed, fully utilizing the device's space for thermal management.

The technical solution of this application is as follows:

A flexible customized 3D heat pipe is disposed in an electronic device and partially contacts a control chip of the electronic device. It includes a flexible housing, a flexible wick, and a working fluid.

The flexible housing forms a working fluid circulation groove therein. The flexible wick is disposed within the working fluid circulation groove. On any cross-section perpendicular to the extending direction of the working fluid circulation groove, the flexible wick contacts both the top surface and the bottom surface of the working fluid circulation groove.

The working fluid circulates within the working fluid circulation groove. The flexible wick absorbs liquid working fluid through capillary action. The liquid working fluid absorbs heat dissipated by the control chip and evaporates into a gaseous state, then dissipates heat through the top and bottom surfaces of the working fluid circulation groove, condenses back into liquid, and flows back onto the flexible wick.

In some possible implementations, a cross-section of the flexible wick perpendicular to its extending direction is a curve of a periodic function, the periodic function being a trigonometric function, a polynomial function, or a Gaussian function.

In some possible implementations, the wavelength of the periodic function is 0.1-2.5 mm, and the amplitude of the periodic function is 0.05-0.75 mm. The width of the working fluid circulation groove is 5-40 mm, and the height is 0.1-1.5 mm.

In some possible implementations, the material of the flexible wick is copper mesh, stainless steel mesh, or iron-chromium-aluminum mesh subjected to hydrophilic treatment. The flexible housing is formed by compositing two polymer layers and a metal layer disposed between the two polymer layers. The material of the metal layer is copper, aluminum, or stainless steel. The material of the polymer layer is low-density polyethylene terephthalate, polypropylene, or polyethylene.

In some possible implementations, the flexible wick is obtained by stacking and pressing multiple layers of the copper mesh, stainless steel mesh, or iron-chromium-aluminum mesh subjected to hydrophilic treatment. The method for hydrophilic treatment is a coating method, an anodization method, or a chemical deposition method.

This application imposes no restrictions on the working fluid of the customized 3D heat pipe. Any working fluid commonly used by those skilled in the art that does not react with the flexible wick and flexible housing can be selected. Illustratively, the working fluid can be selected from at least one of deionized water, ethanol, and methanol.

A preparation method for the customized 3D heat pipe described above includes the following steps:
(1) Convert a target model into point cloud data, then plan the morphological trajectory of the customized 3D heat pipe along its two-phase circulation direction based on the point cloud data.

Wherein the flexible housing is formed by sealingly covering an upper housing and a lower housing. The upper housing and lower housing form two ports after being covered. The upper housing and lower housing each have a sealable edge provided on their outer periphery except at positions corresponding to the ports.

The morphological trajectory includes the sealable edges and regions where the curvature of the customized 3D heat pipe changes abruptly.
(2) Extract three-dimensional point coordinates from the morphological trajectory. Generate a three-dimensional surface from three-dimensional sheets along adjacent morphological trajectories in three-dimensional modeling software. Unfold and convert the three-dimensional surface into a two-dimensional unfolded plane using a two-dimensional mapping algorithm. Then prepare an upper housing sheet, a lower housing sheet, a wick sheet, and a flexible heater having the same shape as the sealable edges along the two-dimensional unfolded plane.
(3) Generate a three-dimensional model of a shaping mold for the flexible wick and a three-dimensional model of a pre-encapsulation mold for the customized 3D heat pipe by combining the three-dimensional surface and the morphological trajectory. Then print the shaping mold and pre-encapsulation mold using light-curing 3D printing technology.

Wherein the shaping mold includes an upper shaping mold and a lower shaping mold. The middle portion of the mating surfaces of the upper shaping mold and lower shaping mold has the same shape as the flexible wick.

The pre-encapsulation mold includes an upper pre-encapsulation mold and a lower pre-encapsulation mold. The middle portion of the mating surfaces of the upper pre-encapsulation mold and lower pre-encapsulation mold forms a shape identical to that of the customized 3D heat pipe.
(4) Stack multiple pieces of the wick sheet and place them between the upper shaping mold and the lower shaping mold. The mating of the upper shaping mold and lower shaping mold applies a normal force to the wick sheets to obtain a three-dimensional wick. Subject the three-dimensional wick to hydrophilic treatment to obtain the flexible wick.
(5) Stack the upper pre-encapsulation mold, the flexible heater, the upper housing sheet, the flexible wick, the lower housing sheet, and the lower pre-encapsulation mold sequentially. The mating of the upper pre-encapsulation mold and lower pre-encapsulation mold applies a normal force to the upper housing sheet and lower housing sheet. Heat the flexible heater to seal the sealable edges, obtaining a pre-encapsulated heat pipe. The outer periphery of the pre-encapsulated heat pipe not sealed by the sealable edges forms two ports.
(6) Perform a drainage port treatment on one of the ports, then seal the other port. Evacuate and fill the pre-encapsulated heat pipe with working fluid from the port subjected to drainage port treatment. Finally, seal the port subjected to drainage port treatment, obtaining the customized 3D heat pipe.

In the above steps, step (1) is performed using three-dimensional data processing software. Generating the three-dimensional surface sheets along the three-dimensional point coordinates in step (2) is implemented using three-dimensional modeling software. The generation of the three-dimensional models in step (3) is implemented using computer-aided design (CAD) software. This application imposes no limitations on the specific software and algorithms used in the preparation method, as long as the corresponding functions are achieved. Illustratively, the three-dimensional data processing software can be MeshLab, CloudCompare, Autodesk Recap, or Blender; the three-dimensional modeling software can be Matlab, Autodesk 3ds Max, or Rhinoceros; the two-dimensional mapping algorithm can be the minimum energy unfolding method, conformal mapping, or isometric mapping; the CAD software can be Solidworks, UG, or Catia.

In some possible implementations, the light-curing 3D printing technology is stereolithography (SLA), digital light processing (DLP), continuous liquid interface production (CLIP), or masked stereolithography (MSLA).

In some possible implementations, the materials for the shaping mold and the pre-encapsulation mold are independently selected from epoxy resin, phenolic resin, or ceramic resin.

In some possible implementations, the operation of applying a normal force to the wick sheets by mating the upper shaping mold and lower shaping mold is: locking the upper shaping mold and lower shaping mold together using bolts and nuts, then standing for 30 s-30 min. The operation of applying a normal force to the upper housing sheet and lower housing sheet by mating the upper pre-encapsulation mold and lower pre-encapsulation mold is: locking the upper pre-encapsulation mold and lower pre-encapsulation mold together using bolts and nuts, then standing for 30 s-30 min.

In some possible implementations, the specific operation for the drainage port treatment is: setting a copper tube to the port by hot pressing.

In some possible implementations, the morphological trajectory is laid along the contour of the electronic device.

In some possible implementations, the method for preparing the upper housing sheet, lower housing sheet, wick sheet, and flexible heater with the same shape as the sealable edges along the two-dimensional unfolded plane is achieved through planar cutting processes, which can be laser cutting, die cutting, or knife cutting.

In some possible implementations, the flexible heater is strip-shaped and is a carbon cloth heater or a polyimide heater.

An electronic device includes the customized 3D heat pipe described above and dissipates heat through the customized 3D heat pipe.

The customized 3D heat pipe provided by this application can be used for heat dissipation in any electronic device, and is particularly suitable for some emerging electronic devices with complex configurations, such as VR headsets, AR glasses, cameras, and drones.

This application has at least the following beneficial effects:
1. The customized 3D heat pipe of this application partially contacts the control chip to absorb the heat it generates. The remaining part can be laid along any three-dimensional path within the electronic device as needed. The heat accumulated by the control chip is then transferred to any spatial region within the device where the heat pipe is laid. This maximizes the heat dissipation area of the heat pipe without affecting the device's volume or the installation space of other components. Compared to traditional 2D flat heat pipes, it enables more efficient spatial thermal management for electronic devices.
2. In some possible implementations, the customized 3D heat pipe includes a metal flexible wick and a flexible housing composed of a metal layer and polymer layers. Traditional metal heat pipes mostly have wall thicknesses on the millimeter scale to ensure sealing, leading to high overall weight. The composite shell of this application introduces polymer layers (made of high-temperature resistant plastics), significantly reducing the mass of the customized 3D heat pipe while ensuring sealing performance, improving its flexibility, and lowering costs. This makes it possible to manufacture complex-shaped customized 3D heat pipes using 3D printing technology.
3. The preparation method of this application uses light-curing 3D printing to produce the shaping mold and pre-encapsulation mold, then uses these molds to shape the flexible wick and pre-encapsulate the customized 3D heat pipe. Compared to mainstream solutions that directly use SLM to print heat pipes, this method reduces both the cost of 3D printing technology and material costs. It also reduces the mass of the customized 3D heat pipe, increases design freedom, and lowers the cost required for customization.

### BRIEF DESCRIPTION OF THE DRAWINGS

FIG. 1 is a VR headset device and the customized 3D heat pipe for the VR headset device;

FIG. 2 is a schematic structural diagram of a cross-section of the customized 3D heat pipe perpendicular to its extending direction;

FIG. 3 is an assembly diagram for shaping the flexible wick;

FIG. 4 is an assembly diagram during the preparation of the pre-encapsulated heat pipe;

FIG. 5 is a comparison diagram of the heat dissipation effect between the customized 3D heat pipe and traditional heat pipes in a VR headset device.

Reference Numerals: 1-customized 3 D heat pipe; 11-flexible housing; 111-working fluid circulation groove; 12-flexible wick; 21-upper shaping mold; 22-lower shaping mold; 23-wick sheet; 31-upper pre-encapsulation mold; 32-lower pre-encapsulation mold; 33-flexible heater; 34-upper housing sheet; 35-lower housing sheet; 41-screw hole; 42-nut; 43-bolt; 5-VR headset; 51-main body; 52-strap.

### DETAILED DESCRIPTION OF THE EMBODIMENTS

In order to clarify the objectives, technical scheme and advantages of the invention, the invention is described in more detail combined with the following drawings and specific embodiments, but the scope of protection of the invention is not limited to these embodiments. The same reference marks in the text always represent the same elements, and the similar reference marks represent similar elements.

In the description of the present invention, it is necessary to be understood that the terms “up”, “down”, “front”, “back”, “after”, “left”,

The orientation or position relationship such as “right”, “horizontal”, “vertical”, “top”, “bottom”, “inside”, “outside” are based on the orientation or position relationship shown in the stereodiagram in the attached drawings, only to facilitate the description of the invention and simplify the description, rather than indicating or implying that the device or element must be constructed and operated in a specific orientation, and thus cannot be understood as a limitation of the present invention.

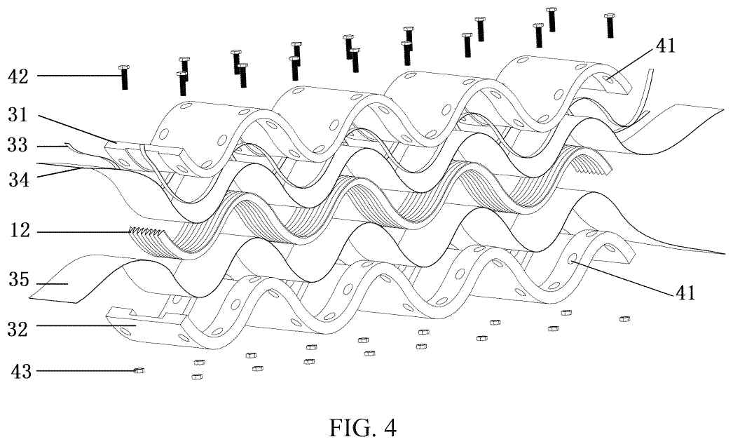

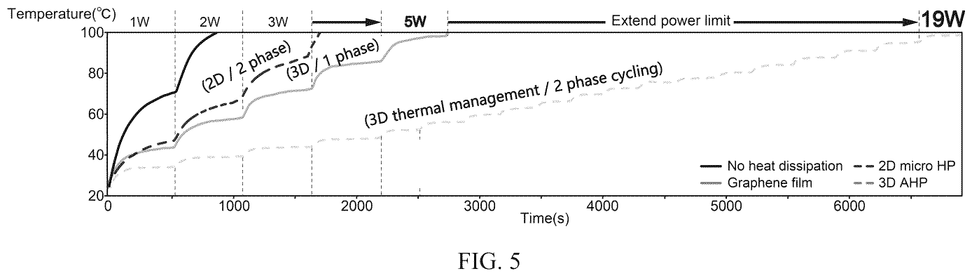

The upper shaping mold 21, lower shaping mold 22, upper pre-encapsulation mold 31, lower pre-encapsulation mold 32, flexible heater 33, upper housing sheet 34, lower housing sheet 35, and flexible wick 12 in FIGS. 4-5 are shown as long wavy strips. This is merely to illustrate that these components can be designed into any shape as needed, and does not limit their shapes.

The technical solution of this application is further illustrated and described below through embodiments.

### Example 1

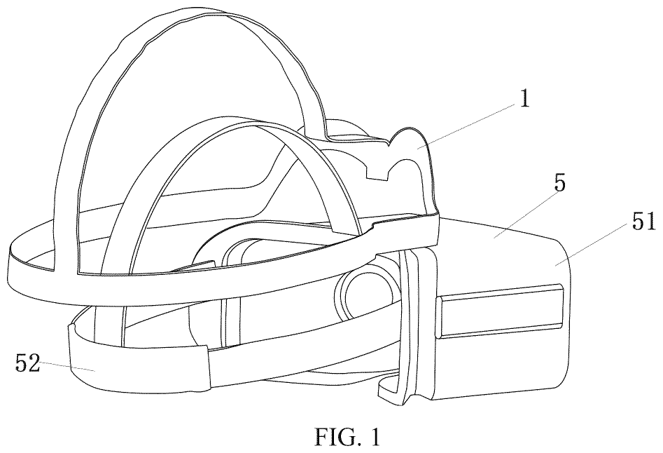

This example prepares a customized 3D heat pipe 1 for a VR headset 5. The VR headset 5 includes a main body 51 and a strap 52. The main body 51 houses a control chip. As can be seen from FIG. 1, part of the shape of the customized 3D heat pipe 1 matches the main body 51, while a large part matches the shape of the strap 52. In actual assembly, part of the customized 3D heat pipe 1 is disposed within the main body 51 and contacts the control chip, while the remaining part is disposed within the strap 52 to maximize the space for thermal management.

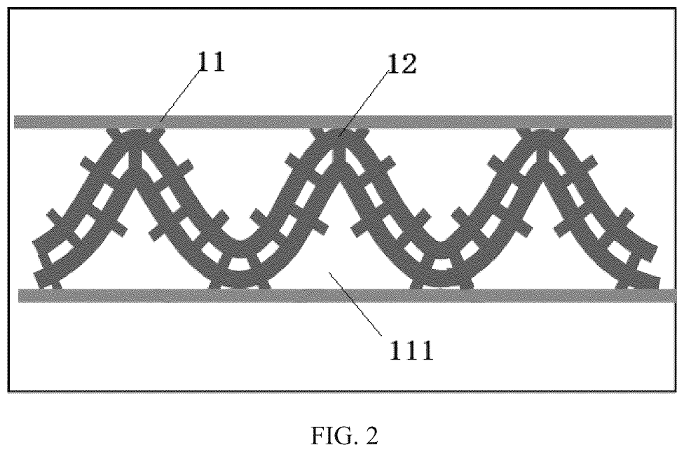

As shown in FIG. 2, the flexible customized 3D heat pipe 1 includes a flexible housing 11, a flexible wick 12, and a working fluid. The flexible housing 11 forms a working fluid circulation groove 111 therein. The flexible wick 12 is disposed within the working fluid circulation groove 111. On any cross-section perpendicular to the extending direction of the working fluid circulation groove 111, the flexible wick 12 contacts both the top surface and the bottom surface of the working fluid circulation groove 111. The working fluid circulates within the working fluid circulation groove 111. The flexible wick 12 absorbs liquid working fluid through capillary action. The liquid working fluid absorbs heat dissipated by the control chip and evaporates into a gaseous state, then dissipates heat through the top and bottom surfaces of the working fluid circulation groove 111, condenses back into liquid, and flows back onto the flexible wick 12. This configuration achieves a planar two-phase cycle of the working fluid (liquid and vapor coexisting in the same plane), giving the customized 3D heat pipe 1 a smaller thickness.

Specifically, in this example, the cross-section of the flexible wick 12 is a curve of a polynomial function. The period of this polynomial function is 1.5 mm, and the amplitude is 0.5 mm (the thickness of the flexible wick 12 is twice the amplitude, i.e., 1 mm).

In this example, the flexible housing 11 is a metal-plastic composite shell material formed by compositing two polymer layers and a metal layer sandwiched between them. The polymer layer material is polypropylene, and the metal layer material is aluminum. The flexible wick 12 is a multi-layer self-supporting copper mesh subjected to hydrophilic treatment.

The preparation method for the customized 3D heat pipe 1 in this example includes the following steps:
(1) Import a target three-dimensional model in STL format into three-dimensional data processing software. Convert the target model into point cloud data using the software, then plan the morphological trajectory of the customized 3D heat pipe 1 along its two-phase circulation direction based on the point cloud data.

Wherein the flexible housing 11 of the customized 3D heat pipe 1 includes an upper housing and a lower housing that are covered and sealed. The upper and lower housings form two ports after being covered. The upper and lower housings each have a sealable edge provided on their outer periphery except at positions corresponding to the ports.

The morphological trajectory includes the sealable edges and regions where the curvature of the customized 3D heat pipe 1 changes abruptly.

In this step, the three-dimensional data processing software is CloudCompare.
(2) Extract three-dimensional point coordinates from the morphological trajectory. Generate a three-dimensional surface from three-dimensional sheets along adjacent morphological trajectories in three-dimensional modeling software. Unfold and convert the three-dimensional surface into a two-dimensional unfolded plane using a two-dimensional mapping algorithm. Then prepare the upper housing sheet 34, lower housing sheet 35, wick sheet 23, and flexible heater 33 having the same shape as the sealable edges along the two-dimensional unfolded plane by laser cutting. In this example, the flexible heater 33 is a carbon cloth heater. Voltage is applied to the flexible heater 33 to generate heat.

In this step, the three-dimensional modeling software is Matlab, and the two-dimensional mapping algorithm is conformal mapping.
(3) Generate a three-dimensional model of a shaping mold for the flexible wick 12 and a three-dimensional model of a pre-encapsulation mold for the customized 3D heat pipe 1 in CAD software by combining the three-dimensional surface and the morphological trajectory. Then print the shaping mold and pre-encapsulation mold using light-curing 3D printing technology.

Wherein the shaping mold includes an upper shaping mold 21 and a lower shaping mold 22. The middle portion of the mating surfaces of the upper shaping mold 21 and lower shaping mold 22 has the same shape as the flexible wick 12.

The pre-encapsulation mold includes an upper pre-encapsulation mold 31 and a lower pre-encapsulation mold 32. The middle portion of the mating surfaces of the upper pre-encapsulation mold 31 and lower pre-encapsulation mold 32 forms a shape identical to that of the customized 3D heat pipe 1.

In this step, the CAD software is Solidworks. The light-curing 3D printing technology is Digital Light Processing (DLP). The materials for the shaping mold and pre-encapsulation mold are phenolic-based high-temperature resistant photosensitive resin.
(4) Stack multiple pieces of the wick sheet 23 and place them between the upper shaping mold 21 and the lower shaping mold 22. The mating of the upper shaping mold 21 and lower shaping mold 22 applies a normal force to the wick sheets 23 to obtain a three-dimensional wick. Subject the three-dimensional wick to hydrophilic treatment to obtain the flexible wick 12.
(5) Stack the upper pre-encapsulation mold 31, the flexible heater 33, the upper housing sheet 34, the flexible wick 12, the lower housing sheet 35, and the lower pre-encapsulation mold 32 sequentially. The mating of the upper pre-encapsulation mold 31 and lower pre-encapsulation mold 32 applies a normal force to the upper housing sheet 34 and lower housing sheet 35. Heat the flexible heater 33 to seal the sealable edges, obtaining a pre-encapsulated heat pipe. The outer periphery of the pre-encapsulated heat pipe not sealed by the sealable edges forms two ports.
(6) Perform a drainage port treatment on one of the ports, then seal the other port. Evacuate and fill the pre-encapsulated heat pipe with working fluid from the port subjected to drainage port treatment. Finally, seal the port subjected to drainage port treatment, obtaining the customized 3D heat pipe 1.

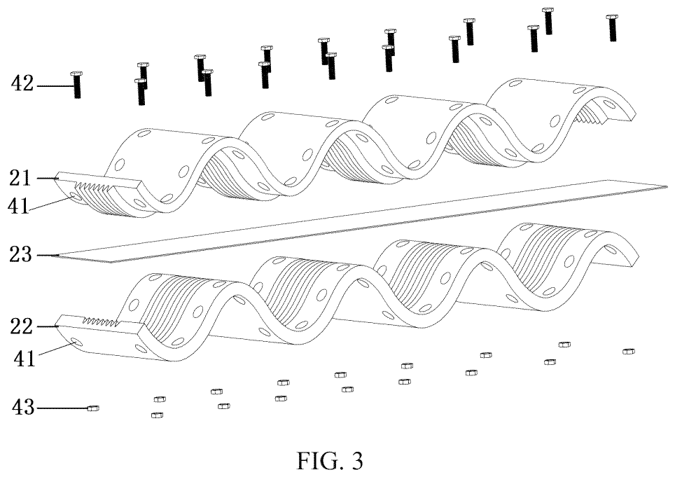

Steps (4) and (5) are further explained below with reference to FIGS. 3-4.

First, referring to FIG. 3, the mating surfaces of the upper shaping mold 21 and lower shaping mold 22 have a periodic contour surface obtained by sweeping the curve of the periodic function along the planned trajectory. The period of this function is 1.5 mm, and the amplitude is 0.5 mm. The non-mating surfaces of the upper shaping mold 21 and lower shaping mold 22 are free-form surfaces obtained by sweeping straight lines along the planned trajectory.

Screw holes 41 are opened on both sides along the extending direction of the upper shaping mold 21 and lower shaping mold 22, and they cooperate with each other. The upper shaping mold 21 and lower shaping mold 22 can be locked together using bolts 43 and nuts 42.

Place the wick sheet 23 between the upper shaping mold 21 and lower shaping mold 22. Then pass nuts 42 sequentially through the screw holes 41 on the upper shaping mold 21 and lower shaping mold 22. Lock them together using bolts 43 and nuts 42 to apply a normal force to the wick sheet 23. Stand for 2 min, then loosen the bolts 43 and nuts 42. The wick sheet 23 is shaped by the upper shaping mold 21 and lower shaping mold 22, obtaining a three-dimensional wick with a periodic contour surface. Subject the three-dimensional wick to hydrophilic treatment to obtain the flexible wick 12.

As shown in FIG. 4, the mating surfaces of the upper pre-encapsulation mold 31 and lower pre-encapsulation mold 32 form a curved rectangular groove extending along the planned trajectory in the middle portion. Along their extending direction, both sides of the upper pre-encapsulation mold 31 and lower pre-encapsulation mold 32 form contact surfaces that meet. The width of the curved rectangular groove is 15 mm, and the height is 1 mm. The non-mating surfaces of the upper pre-encapsulation mold 31 and lower pre-encapsulation mold 32 are free-form surfaces obtained by sweeping straight lines along the planned trajectory.

Screw holes 41 are opened on the contact surfaces of the upper pre-encapsulation mold 31 and lower pre-encapsulation mold 32, and they cooperate with each other. The upper pre-encapsulation mold 31 and lower pre-encapsulation mold 32 can be locked together using bolts 43 and nuts 42.

The width of the upper housing sheet 34 and lower housing sheet 35 is slightly larger than the width of the curved rectangular groove. This ensures that the parts on both sides of the upper housing sheet 34, which serve as the sealable edges of the upper housing, do not enter the curved rectangular groove and do not contact the screw holes 41. The same applies to the lower housing sheet.

Stack the upper pre-encapsulation mold 31, flexible heater 33, upper housing sheet 34, flexible wick 12, lower housing sheet 35, and lower pre-encapsulation mold 32 sequentially. The shape and position of the flexible heater 33 correspond to the sealable edges. Then pass nuts 42 sequentially through the screw holes on the upper pre-encapsulation mold 31 and lock them using bolts 43 and nuts 42 to apply a normal force to the upper housing sheet 34 and lower housing sheet 35. Stand for 15 min, then loosen the bolts 43 and nuts 42. The upper housing sheet 34 and lower housing sheet 35 are shaped to form the upper housing and lower housing. A working fluid circulation groove accommodating the flexible wick 12 is formed between the upper and lower housings. Subsequently, heat the flexible heater 33 to seal the sealable edges of the upper housing sheet 34 and lower housing sheet 35, obtaining the pre-encapsulated heat pipe. All sides of the pre-encapsulated heat pipe except the two ports are sealed.

Perform drainage port treatment on one port, then seal the other port. Evacuate and fill the pre-encapsulated heat pipe with working fluid from the port subjected to drainage port treatment. Finally, seal the port subjected to drainage port treatment, obtaining the customized 3D heat pipe 1 of this example.

FIG. 5 is a comparison diagram of the heat dissipation effect between the customized 3D heat pipe 1 and several existing heat pipes in a VR headset 5 device. It can be seen that under the same heating power, the customized 3D heat pipe 1 can reduce the absolute temperature by approximately 40%-50% and increase the maximum heating power by 3-5 times.

The above descriptions are merely preferred embodiments of this application and are not intended to limit the scope of this application. Any equivalent changes or modifications made according to the patent scope and content of the description of this application should still fall within the scope covered by this application.

What is claimed is:

1. A preparation method for a customized three dimensional (3D) heat pipe, wherein the customized 3D heat pipe is disposed in an electronic device and partially contacts a control chip of the electronic device, and comprises a flexible housing, a flexible wick, and a working fluid;
wherein the flexible housing forms a working fluid circulation groove therein, the flexible wick is disposed within the working fluid circulation groove, and on any cross-section perpendicular to an extending direction of the working fluid circulation groove, the flexible wick contacts both a top surface and a bottom surface of the working fluid circulation groove;
the working fluid circulates within the working fluid circulation groove, the flexible wick absorbs a liquid working fluid through capillary action, and the liquid working fluid absorbs heat dissipated by the control chip and evaporates into a gaseous state, then dissipates heat through the top surface and the bottom surface of the working fluid circulation groove to condense into liquid and flow back onto the flexible wick;
the preparation method comprises the following steps:
(1) converting a target model into point cloud data, and then planning a morphological trajectory of the customized 3D heat pipe along its two-phase circulation direction based on the point cloud data;
wherein the flexible housing is obtained by sealingly covering an upper housing and a lower housing, the upper housing and the lower housing forming two ports after being covered; and the upper housing and the lower housing each are provided with a thermally sealable edge at their outer periphery except at positions corresponding to the ports;
the morphological trajectory comprises sealable edges and regions where a curvature of the customized 3D heat pipe changes abruptly;
(2) extracting three-dimensional point coordinates from the morphological trajectory, generating a three-dimensional surface from three-dimensional sheets along adjacent morphological trajectories in a three-dimensional modeling software, unfolding and converting the three-dimensional surface into a two-dimensional unfolded plane using a two-dimensional mapping algorithm, then preparing an upper housing sheet, a lower housing sheet, a wick sheet, and a flexible heater having the same shape as the sealable edges along the two-dimensional unfolded plane;
(3) generating a three-dimensional model of a shaping mold for the flexible wick and a three-dimensional model of a pre-encapsulation mold for the customized 3D heat pipe by combining the three-dimensional surface and the morphological trajectory, and then printing the shaping mold and the pre-encapsulation mold using light-curing 3D printing technology;
wherein the shaping mold comprises an upper shaping mold and a lower shaping mold, and a middle portion of mating surfaces of the upper shaping mold and the lower shaping mold has the same shape as the flexible wick; and
the pre-encapsulation mold comprises an upper pre-encapsulation mold and a lower pre-encapsulation mold, and a middle portion of mating surfaces of the upper pre-encapsulation mold and the lower pre-encapsulation mold forms a shape identical to that of the customized 3D heat pipe;
(4) stacking multiple pieces of the wick sheet and placing them between the upper shaping mold and the lower shaping mold, mating of the upper shaping mold and the lower shaping mold applying a normal force to wick sheets to obtain a three-dimensional wick, and subjecting the three-dimensional wick to hydrophilic treatment to obtain the flexible wick;
(5) sequentially stacking the upper pre-encapsulation mold, the flexible heater, the upper housing sheet, the flexible wick, the lower housing sheet, and the lower pre-encapsulation mold, mating of the upper pre-encapsulation mold and the lower pre-encapsulation mold applying a normal force to the upper housing sheet and the lower housing sheet, heating the flexible heater to seal the sealable edges, and obtaining a pre-encapsulated heat pipe, an outer periphery of the pre-encapsulated heat pipe not sealed by the sealable edges forming the two ports; and
(6) performing a drainage port treatment on one of the ports, then sealing the other port, evacuating and filling the pre-encapsulated heat pipe with the working fluid from a port subjected to the drainage port treatment, finally sealing the port subjected to the drainage port treatment, and obtaining the customized 3D heat pipe.

2. The preparation method according to claim 1, wherein a cross-section of the flexible wick perpendicular to its extending direction is a curve of a periodic function, the periodic function being a trigonometric function, a polynomial function, or a Gaussian function.

3. The preparation method according to claim 2, wherein a wavelength of the periodic function is 0.1-2.5 mm, and an amplitude of the periodic function is 0.05-0.75 mm; and
a width of the working fluid circulation groove is 5-40 mm, and a height is 0.1-1.5 mm.

4. The preparation method according to claim 1, wherein a material of the flexible wick is a copper mesh, a stainless steel mesh, or an iron-chromium-aluminum mesh subjected to the hydrophilic treatment; and
the flexible housing is obtained by compositing two polymer layers and a metal layer disposed between the two polymer layers, a material of the metal layer is copper, aluminum, or stainless steel, and a material of the polymer layer is low-density polyethylene terephthalate, polypropylene, or polyethylene.

5. The preparation method according to claim 4, wherein the flexible wick is obtained by stacking and pressing multiple layers of the copper mesh, the stainless steel mesh, or the iron-chromium-aluminum mesh subjected to the hydrophilic treatment; and
a method for the hydrophilic treatment is a coating method, an anodization method, or a chemical deposition method.

6. The preparation method according to claim 1, wherein the light-curing 3D printing technology is stereolithography (SLA), digital light processing (DLP), continuous liquid interface production (CLIP), or masked stereolithography (MSLA);
and/or, materials for the shaping mold and the pre-encapsulation mold are independently selected from epoxy resin, phenolic resin, or ceramic resin.

7. The preparation method according to claim 1, wherein an operation of applying the normal force to the wick sheets by mating the upper shaping mold and the lower shaping mold is: locking the upper shaping mold and the lower shaping mold together using bolts and nuts, and then letting stand for 30 s to 30 min; and
an operation of applying the normal force to the upper housing sheet and the lower housing sheet by mating the upper pre-encapsulation mold and the lower pre-encapsulation mold is:
locking the upper pre-encapsulation mold and the lower pre-encapsulation mold together using bolts and nuts, and then letting stand for 30 s to 30 min.

8. The preparation method according to claim 1, wherein a specific operation for the drainage port treatment is: setting a copper tube at the port by hot pressing.

9. An electronic device, comprising the customized 3D heat pipe obtained by the preparation method according to claim 1, and dissipating heat through the customized 3D heat pipe.

10. The preparation method according to claim 2, wherein a material of the flexible wick is a copper mesh, a stainless steel mesh, or an iron-chromium-aluminum mesh subjected to the hydrophilic treatment; and
the flexible housing is obtained by compositing two polymer layers and a metal layer disposed between the two polymer layers, a material of the metal layer is copper, aluminum, or stainless steel, and a material of the polymer layer is low-density polyethylene terephthalate, polypropylene, or polyethylene.

11. The preparation method according to claim 3, wherein a material of the flexible wick is a copper mesh, a stainless steel mesh, or an iron-chromium-aluminum mesh subjected to the hydrophilic treatment; and
the flexible housing is obtained by compositing two polymer layers and a metal layer disposed between the two polymer layers, a material of the metal layer is copper, aluminum, or stainless steel, and a material of the polymer layer is low-density polyethylene terephthalate, polypropylene, or polyethylene.

12. The preparation method according to claim 6, wherein an operation of applying the normal force to the wick sheets by mating the upper shaping mold and the lower shaping mold is:
locking the upper shaping mold and the lower shaping mold together using bolts and nuts, and then letting stand for 30 s to 30 min; and
an operation of applying the normal force to the upper housing sheet and the lower housing sheet by mating the upper pre-encapsulation mold and the lower pre-encapsulation mold is:
locking the upper pre-encapsulation mold and the lower pre-encapsulation mold together using bolts and nuts, and then letting stand for 30 s to 30 min.

13. The preparation method according to claim 6, wherein a specific operation for the drainage port treatment is: setting a copper tube at the port by hot pressing.

14. The electronic device according to claim 9, wherein in the preparation method, a cross-section of the flexible wick perpendicular to its extending direction is a curve of a periodic function, the periodic function being a trigonometric function, a polynomial function, or a Gaussian function.

15. The electronic device according to claim 14, wherein in the preparation method, a wavelength of the periodic function is 0.1-2.5 mm, and an amplitude of the periodic function is 0.05-0.75 mm; and
a width of the working fluid circulation groove is 5-40 mm, and a height is 0.1-1.5 mm.

16. The electronic device according to claim 9, wherein in the preparation method, a material of the flexible wick is a copper mesh, a stainless steel mesh, or an iron-chromium-aluminum mesh subjected to the hydrophilic treatment; and
the flexible housing is obtained by compositing two polymer layers and a metal layer disposed between the two polymer layers, a material of the metal layer is copper, aluminum, or stainless steel, and a material of the polymer layer is low-density polyethylene terephthalate, polypropylene, or polyethylene.

17. The electronic device according to claim 16, wherein in the preparation method, the flexible wick is obtained by stacking and pressing multiple layers of the copper mesh, the stainless steel mesh, or the iron-chromium-aluminum mesh subjected to the hydrophilic treatment; and
a method for the hydrophilic treatment is a coating method, an anodization method, or a chemical deposition method.

18. The electronic device according to claim 9, wherein in the preparation method, the light-curing 3D printing technology is SLA, DLP, CLIP, or MSLA;
and/or, materials for the shaping mold and the pre-encapsulation mold are independently selected from epoxy resin, phenolic resin, or ceramic resin.

19. The electronic device according to claim 9, wherein in the preparation method, an operation of applying the normal force to the wick sheets by mating the upper shaping mold and the lower shaping mold is: locking the upper shaping mold and the lower shaping mold together using bolts and nuts, and then letting stand for 30 s to 30 min; and
an operation of applying the normal force to the upper housing sheet and the lower housing sheet by mating the upper pre-encapsulation mold and the lower pre-encapsulation mold is:
locking the upper pre-encapsulation mold and the lower pre-encapsulation mold together using bolts and nuts, and then letting stand for 30 s to 30 min.

20. The electronic device according to claim 9, wherein in the preparation method, a specific operation for the drainage port treatment is: setting a copper tube at the port by hot pressing.
